(19) United States
(12) Patent Application Publication
(10) Pub. No.: US 2019/0068416 A1
(43) Pub. Date: Feb. 28, 2019

(54) PHASE ERROR DETECTING MODULE AND PHASE ERROR DETECTION METHOD

(71) Applicant: MStar Semiconductor, Inc., Hsinchu Hsien (TW)

(72) Inventors: Ting-Nan CHO, Hsinchu Hsien (TW); Kai-Wen CHENG, Hsinchu Hsien (TW); Tai-Lai TUNG, Hsinchu Hsien (TW)

(21) Appl. No.: 15/994,285

(22) Filed: May 31, 2018

(30) Foreign Application Priority Data
Aug. 29, 2017 (TW) 106129314

(51) Int. Cl. H04L 27/00; H03L 7/08; H04L 27/20

(52) U.S. Cl. CPC H04L 27/0014; H04L 2027/0067; H04L 27/20; H03L 7/0807

(57) ABSTRACT

A phase error detection module includes: a constellation point selector, generating a constellation point selection signal according to a position and a radius of data of an input signal in a constellation diagram; a symbol estimator, selecting a part of all of a plurality of constellation points in the constellation diagram according to the constellation point selection signal, as a plurality of reference constellation points for calculating an estimated symbol corresponding to the data of the input signal, and a quantity of the reference constellation points is smaller than a quantity of all of the constellation points of the constellation diagram; and a phase estimator, calculating an estimated phase error of the input signal according to the data of the input signal and the estimated symbol.

This application claims the benefit of Taiwan application Serial No. 106129314, filed on Aug. 29, 2017, the subject matter of which is incorporated herein by reference.

### BACKGROUND OF THE INVENTION

### Field of the Invention

The invention relates to a phase error detection module and a phase error detection method for a phase recovery apparatus, and more particularly to a phase error detection module and an phase error detection method that adjust, according to characteristics of an input signal, a basis for calculating a phase error.

### Description of the Related Art

A phase-locked loop (PLL) circuit is used to generate a periodic output signal, which is expected to have a fixed phase relation with a periodic input signal. PLL circuits are extensively applied in diversified circuit systems, for example, clock and data recovery circuits, transceivers and frequency synthesizers in wireless communication systems.

FIG. 1 shows a block diagram of a phase error detector 10. The phase error detector 10 detects a phase error of an input signal IN to generate an estimated phase error EPE, according to which a PLL circuit (not shown) generates a phase compensation signal (not shown) for correcting the phase of the input signal IN. As shown in FIG. 1, the phase error detector 10 includes a symbol estimator 100 and a phase evaluator 102. The symbol estimator 100 estimates a symbol corresponding to data of the input signal IN to generate an estimated symbol ES in the input signal IN. The phase evaluator 102 evaluates a difference between the data of the input signal IN and the corresponding estimated symbol ES to generate the estimated phase error EPE of the input signal IN.

In general, the symbol estimator 100 needs to calculate the relation between the data of the input signal and all constellation points of the modulation schemes by the input signal IN to obtain the estimated symbol ES corresponding to the data of the input signal IN. With the increase in the number of constellation points used in modulation schemes, computation resources and hardware costs involved by the symbol estimator 100 are drastically increased. Therefore, there is a need for a solution for reducing the computation resources and hardware costs involved by the symbol estimator 100.

### SUMMARY OF THE INVENTION

To solve the above issue, the present invention provides a phase error detection module and an phase error detection method that adjust, according to characteristics of an input signal, a basis for calculating a phase error.

According to an aspect of the present invention, a phase error detection module is disclosed. The phase error detection module includes: a constellation point selector, generating a constellation point selection signal according to a position and a radius of data of an input signal in a constellation diagram; a symbol estimator, selecting a part of all of a plurality of constellation points of the constellation diagram according to the constellation point selection signal, wherein the selected constellation points are used as a plurality of reference constellation points for calculating an estimated symbol corresponding to the data of the input signal, and a quantity of the plurality of reference constellation points is smaller than a quantity of all of the plurality of constellation points of the constellation diagram; and a phase evaluator, calculating an estimated phase error of the input signal according to the data of the input signal and the estimated symbol.

According to another aspect of the present invention, a phase error detection method is disclosed. The phase error detection method includes: generating a constellation point selection signal according to a position and a radius of data of an input signal in a constellation diagram; selecting a part of all of a plurality of constellation points of the constellation diagram according to the constellation point selection signal, wherein the selected constellation points are used as a plurality of reference constellation points for calculating an estimated symbol corresponding to the data of the input signal, and a quantity of the plurality of reference constellation points is smaller than a quantity of all of the plurality of constellation points of the constellation diagram; and calculating an estimated phase error according to the data of the input signal and the estimated symbol.

### BRIEF DESCRIPTION OF THE DRAWINGS

FIG. 1 is a block diagram of a phase error detector;

FIG. 2 is a block diagram of a phase error detection module according to an embodiment of the present invention;

FIG. 3 is a flowchart of a phase error detection method according to an embodiment of the present invention;

FIG. 4 is a block diagram of a constellation point selector according to an embodiment of the present invention;

FIG. 5A and FIG. 5B are schematic diagrams of area dividing methods according to an embodiment of the present invention;

FIG. 6 is a schematic diagram of a mapping table according to an embodiment of the present invention; and

FIG. 7 is a schematic diagram of a symbol estimating unit according to an embodiment of the present invention.

### DETAILED DESCRIPTION OF THE INVENTION

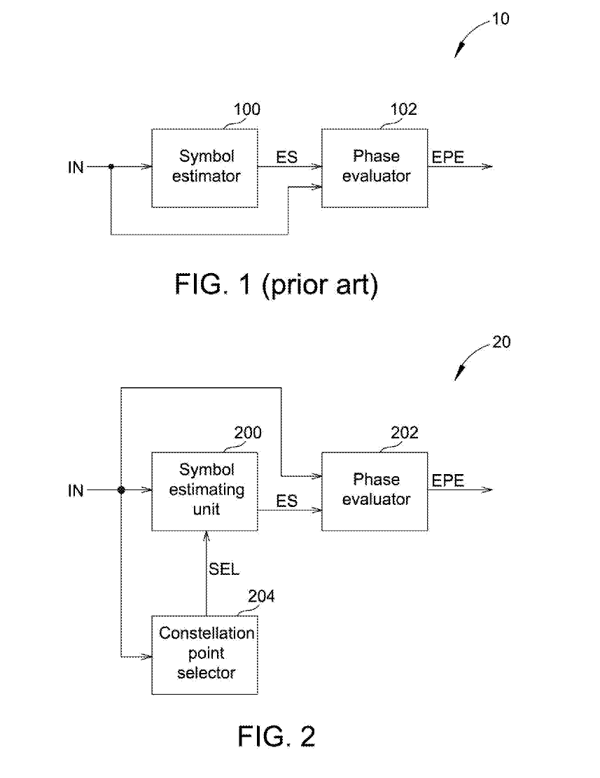

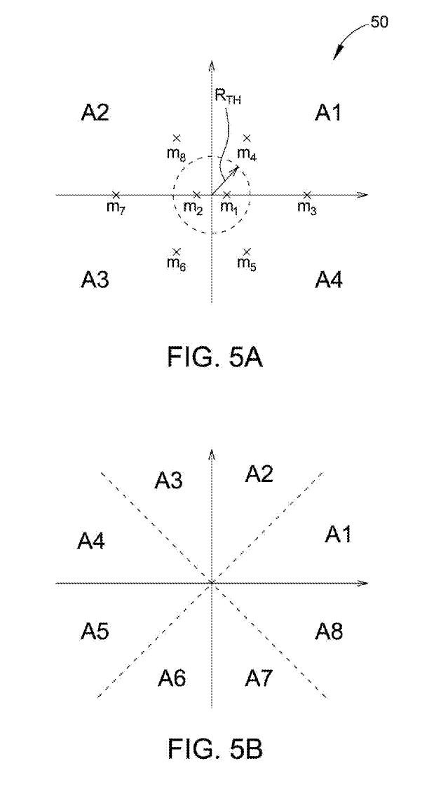

FIG. 2 shows a schematic diagram of a phase error detection module 20 according to an embodiment of the present invention. The phase error detection module 20 is applicable to a phase recovery apparatus of a satellite communication system, and is used to detect a phase error of an input signal IN to generate an estimated phase error EPE. Compared to the phase error detector 10 in FIG. 1, the phase error detection module 20 further includes a constellation point selector 204. The constellation point selector 204 generates, according to a position of data of the input signal IN in a constellation diagram, a constellation point selection signal SEL for controlling a symbol estimating unit 200 to select a part of all constellation points of the constellation diagram as the basis for calculating an estimated symbol ES, i.e., serving as reference constellation points. For example, referring to FIG. 5A showing a schematic diagram of a constellation diagram 50 according to an embodiment of the present invention, the constellation diagram 50 corresponds to 8 amplitude phase shift keying (APSK) modulation, and has eight constellation points m₁ to m₈. The constellation point selector 204 selects from all of the eight constellation points m₁ to m₈, for example, three constellation points m₃, m₄ and m₈ as reference constellation points. Compared to the phase error detector 10 in FIG. 1, because the symbol estimating unit 200 does not use all of the constellation points of the constellation diagram to calculate the estimated symbol ES, the computation resources needed by the symbol estimating unit 200 can be reduced to further lower implementation costs of the phase error detection module 20.

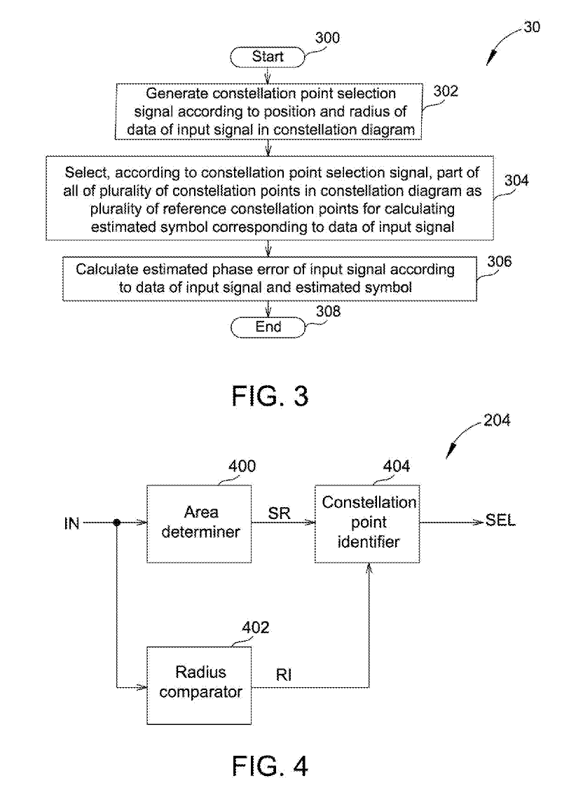

FIG. 3 shows a flowchart of a phase error detection method 30 according to an embodiment of the present invention. Referring to FIG. 2 and FIG. 3, the constellation point selector 204 generates a constellation point selection signal SEL according to a position of data of the input signal in the constellation diagram (step 302). FIG. 4 shows a block diagram of the constellation point selector 204 according to an embodiment of the present invention. Referring to FIG. 4, the constellation point selector 204 includes an area determiner 400, a radius comparator 402 and a constellation point identifier 404.

The area determiner 400 determines in which one of a plurality of areas the position of the data of the input signal is located in the constellation diagram to generate an area indication signal SR. Again referring to FIG. 5A, in one embodiment, the constellation diagram 50 is divided into four areas A1 to A4, which respectively correspond to first to fourth quadrants. In different embodiments, the numbers of the divided areas in the constellation diagram can be appropriately modified. For example, referring to FIG. 5B showing a schematic diagram of a plurality of areas of a divided constellation diagram, the constellation diagram is divided into eight areas A1 to A8, among which the areas A1 and A2 respectively correspond to an upper half and a lower half of the first quadrant, the areas A3 and A4 respectively correspond to an upper half and a lower half of the second quadrant, and so forth.

The radius comparator 402 compares whether the radius R of the data of the input signal IN in the constellation diagram is greater than a radius threshold R_{TH} to generate a radius indication signal RI. In one embodiment, the radius threshold R_{TH} may be an average radius of the constellation points used by the modulation scheme of the input signal IN. Taking FIG. 5A for instance, the radius threshold R_{TH} may be an average radius of the constellation points m₁ to m₈. In another embodiment, the radius threshold R_{TH} may be set according to channel quality; for example, in an environment with a high signal-to-noise ratio (SNR), the radius threshold R_{TH} may be set to 0.

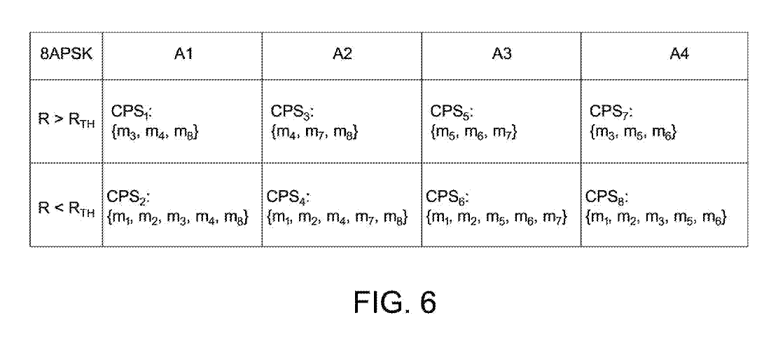

The constellation point identifier 404 generates the constellation point selection signal SEL according to the area indication signal SR and the radius indication signal RI, such that the symbol estimating unit 200 selects, according to the constellation point selection signal SEL, a part of all of the constellation points of the constellation diagram to serve as a plurality of reference constellation points for calculating an estimated symbol corresponding to the data of the input signal IN (step 304). For example, referring to FIG. 6 showing a mapping table of the position and radius of the data of the input signal IN in the constellation diagram and the reference constellation points. When the area indication signal SR indicates that the position of the data of the input signal IN corresponds to the area A1 in the constellation diagram and the radius indication signal RI indicates that the radius R of the data of the input signal IN in the constellation diagram is greater than the radius threshold R_{TH}, it means the data of the input signal IN has a higher probability of corresponding to the constellation points m₃, m₄ and m₈. Thus, the constellation point identifier 404 outputs the constellation point selection signal SEL to control the symbol estimating unit 200 to select a constellation point set CPS₁ including the constellation points m₃, m₄ and m₈ to further calculate the estimated symbol ES. When the area indication signal SR indicates that the data of the input signal IN corresponds to the area A1 and the radius indication signal RI indicates that the radius R is smaller than the radius threshold R_{TH}, it means that the data of the input signal IN has a higher probability of corresponding to the constellation points m₁, m₂, m₃, m₄ and m₈. Thus, the constellation point identifier 404 outputs the constellation point selection signal SEL to control the symbol estimating unit 200 to select a constellation point set CPS₂ including the constellation points m₁, m₂, m₃, m₄ and m₈ to further calculate the estimated symbol ES, and so forth.

In practice, the area determiner 400, the radius comparator 402 and the constellation point identifier 404 may be implemented by hardware, software or firmware. One person skilled in the art can easily conceive of various implementation methods for the area determiner 400, the radius comparator 402 and the constellation point identifier 404, and such details shall be omitted herein.

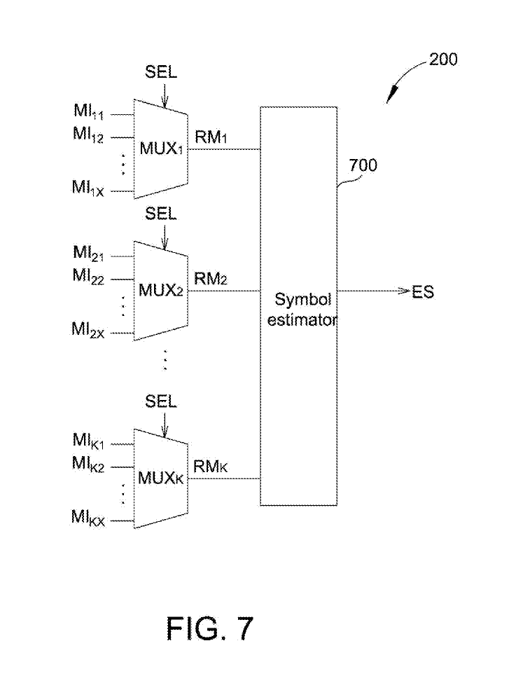

FIG. 7 shows a schematic diagram of implementation of the symbol estimating unit 200 in FIG. 2. In FIG. 7, the symbol estimating unit 200 includes a plurality of multiplexers MUX₁ to MUXₖ and a symbol estimator 700. The number k of the multiplexers MUX₁ to MUXₖ correspond to a maximum number of the numbers of elements in all of the constellation point sets. For example, again referring to FIG. 6, the numbers of elements of the constellation point sets CPS₁, CPS₃, CPS₅ and CPS₇ are all 3, and the numbers of elements of the constellation point sets CPS₂, CPS₄, CPS₆ and CPS₈ are all 5. Thus, in this embodiment, the symbol estimating unit 200 includes five multiplexers (i.e., k=5). The multiplexer MUX₁ has a plurality of inputs MI₁₁ to MI₁ₓ, the multiplexer MUX₂ has a plurality of inputs MI₂₁ to MI₂ₓ, . . . , and the multiplexer MUXₖ has a plurality of inputs MIₖ₁ to MIₖₓ. The number x of inputs of each multiplexer corresponds to the total number of the constellation point sets. For example, again referring to FIG. 6, there are a total of eight constellation point sets (i.e., CPS₁ to CPS₈). Thus, in this embodiment, each multiplexer in the symbol estimating unit 200 has eight inputs (i.e., x=8).

The multiplexer MUX₁ to MUXₖ respectively select, according to the constellation point selection signal SEL, an input from the inputs MI1₁₁ to MI₁ₓ, . . . , and Miₖ₁ to Miₖₓ as reference constellation points RM₁ to RMₖ. In one embodiment, the multiplexer MUX₁ to MUXₖ select, according to the constellation point selection signal SEL, MI₁₁, MI₂₁, . . . and Miₖ₁ as the reference constellation points RM₁ to RMₖ, and the inputs MI₁₁, MI₂₁, . . . and MI₅₁ of the multiplexers MUX₁ to MUX₅ respectively correspond to the elements of the constellation point set CPS₁. Because the constellation point set CPS₁ has only three elements, two inputs among the inputs MI₁₁, MI₂₁, . . . and MI₅₁ are 0, e.g., MI₁₁=m₃, MI₂₁=m₄, MI₃₁=m₈ and MI₄₁=MI₅₁=0. As such, when the multiplexers MUX₁ to MUX₅ output the constellation point set CPS₁, the calculation for the estimated symbol ES is not affected by the reference constellation points RM₄ and RM₅. Further, in this embodiment, the inputs MI₁₂, MI₂₂, . . . and MI₅₂ of the multiplexers MUX₁ to MUX₅ correspond to the elements of the reference constellation point set CPS₂, e.g., MI₁₂=m₁, MI₂₂=m₂, MI₃₂=m₃, MI₄₂=m₄, and MI₅₂=m₈. Similarly, the inputs MI₁₃ to MI₅₂, MI₁₄ to MI₅₄, . . . and MI₁₈ to MI₅₈ of the multiplexers MUX₁ to MUX₅ respectively correspond to elements of the reference constellation point sets CPS₃ to CPS₈.

Next, the symbol estimator 700 applies a minimum mean squared error algorithm according to the reference constellation points RM₁ to RMₖ to generate the estimated symbol ES (step 306). Details of the symbol estimator 700 may be referred from the description associated with the symbol estimator 100, and shall be omitted herein.

After obtaining the estimated symbol ES, the phase evaluator 202 eventually evaluates a difference between the data of the input signal IN and the corresponding estimated symbol ES to generate the estimated phase error EPE of the input signal IN. It should be noted that, various implementation methods of the phase evaluator 202 are generally known to one person skilled in the art, and shall be omitted herein.

In conclusion, the phase error detection module of the present invention is capable of selecting, according to the position and radius of data of an input signal in a constellation diagram, constellation points as the basis for calculating an estimated symbol. Thus, the computation resources needed by the phase error detection module can be reduced to further lower hardware costs of the phase error detection module.

While the invention has been described by way of example and in terms of the embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A phase error detection module, comprising:
a constellation point selector, generating a constellation point selection signal according to a position and a radius of data of an input signal in a constellation diagram;
a symbol estimator, selecting, according to the constellation point selection signal, a part of all of a plurality of constellation points of the constellation diagram, as a plurality of reference constellation points for calculating an estimated symbol corresponding to the data of the input signal, and a quantity of the plurality of reference constellation points is smaller than a quantity of all of the plurality of constellation points; and
a phase evaluator, calculating an estimated phase error of the input signal according to the data of the input signal and the estimated symbol,
wherein the constellation diagram is divided into a plurality of areas, and the constellation point selector comprises:
an area determiner, determining in which one of the plurality of areas the position of the data of the input signal is located in the constellation diagram to generate an area indication signal;
a radius comparator, determining whether the radius of the data of the input signal in the constellation diagram is greater than a radius threshold to generate a radius indication signal; and
a constellation point identifier, generating the constellation point selection signal according to the area indication signal and the radius indication signal.

2. (canceled)

3. The phase error detection module according to claim 1, wherein the symbol estimator comprises:
a plurality of multiplexers, selecting the plurality of reference constellation points from all of the plurality of constellation points according to the constellation point selection signal; and
a symbol estimator, generating the estimated symbol by means of a minimum mean squared algorithm based on the plurality of constellation points.

4. A phase error detection method, comprising:
generating a constellation point selection signal according to a position and a radius of data of an input signal in a constellation diagram;
selecting, according to the constellation point selection signal, a part of all of a plurality of constellation points of the constellation diagram, as a plurality of reference constellation points for calculating an estimated symbol corresponding to the data of the input signal, and a quantity of the plurality of reference constellation points is smaller than a quantity of all of the plurality of constellation points; and
calculating an estimated phase error of the input signal according to the data of the input signal and the estimated symbol,
wherein the constellation diagram is divided into a plurality of areas, and the step of generating the constellation point selection signal according to the position of the data of the input signal in the constellation diagram comprises:
determining in which one of the plurality of areas the position of the data of the input signal is located in the constellation diagram to generate an area indication signal;
determining whether the radius of the data of the input signal in the constellation diagram is greater than a radius threshold to generate a radius indication signal; and
generating the constellation point selection signal according to the area indication signal and the radius indication signal.

5. (canceled)

6. The phase error detection method according to claim 5, wherein the step of selecting, according to the constellation point selection signal, the part of all of a plurality of constellation points of the constellation diagram, as the plurality of reference constellation points for calculating the estimated symbol corresponding to the data of the input signal comprises:
selecting the plurality of reference constellation points from all of the plurality of constellation points according to the constellation point selection signal; and
generating the estimated symbol by means of a minimum mean squared algorithm based on the plurality of constellation points.

7. A phase error detection module, comprising:
a constellation point selector, generating a constellation point selection signal according to a position and a radius of data of an input signal in a constellation diagram;
a symbol estimator, selecting, according to the constellation point selection signal, a part of all of a plurality of constellation points of the constellation diagram, as a plurality of reference constellation points for calculating an estimated symbol corresponding to the data of the input signal, and a quantity of the plurality of reference constellation points is smaller than a quantity of all of the plurality of constellation points; and
a phase evaluator, calculating an estimated phase error of the input signal according to the data of the input signal and the estimated symbol,
wherein the symbol estimator comprises:
a plurality of multiplexers, selecting the plurality of reference constellation points from all of the plurality of constellation points according to the constellation point selection signal; and
a symbol estimator, generating the estimated symbol by means of a minimum mean squared algorithm based on the plurality of constellation points
